(19) United States
(12) Patent Application Publication
(10) Pub. No.: US 2004/0133827 A1
(43) Pub. Date: Jul. 8, 2004

(54) Internal data generation and compare via unused external pins

(75) Inventors: Alan D. Norris, Hinesburg, VT (US); Wolfgang Hokenmaier, Burlington, VT (US); Klaus Nierle, Essex Junction, VT (US)

Correspondence Address: H. Daniel Schnurmann, Intellectual Property Law, IBM Corporation, Dept. 18G, 2070 Route 52, Building 300-482, Hopewell Junction, NY, 12533, US

(73) Assignees: International Business Machines Corporation, Armonk, NY (US); Infineon Technologies North America Corp., San Jose, CA (US)

(21) Appl. No.: 10/336,140

(22) Filed: Jan. 2, 2003

(51) Int. Cl. G11C 29/00

(52) U.S. Cl. 714/718

(57) ABSTRACT

A test operation of a memory array permits changing the test vector during the test by controlling the contents of a test vector through at least two external terminals not used during the test to change from a first to a second test vector, both of said first and second test vectors being stored in a controllable register connected to the external terminals.

### TECHNICAL FIELD

The field of the invention is that of testing integrated circuits having memory arrays.

### BACKGROUND OF THE INVENTION

Standard configurations of current DRAM ICs have typically 16, 8 or 4 I/Os with the address range in their column dimension increasing with lower I/O width. In the case of a 512 Mb IC there are the following standard configurations:

| | | Column | |
|---|---|---|---|
| I/O width | Row addresses | addresses | Relative test time |
| 16 | 13 + 2 | 9 + 2 | 1x |
| 8 | 13 + 2 | 10 + 2 | 2X |
| 4 | 13 + 2 | 11 + 2 | 4x |

The table shows that for the minimal test time the maximum number of I/Os are required.

Any tester platform for integrated circuits (ICs) is limited in I/O channels as the number of I/O channels is a limiting factor for the physical dimensions of the test setup as well as cost. In order to increase the throughput of testing it is desirable to reduce the number of required I/Os per IC.

At the same time the flexibility for generating any desired data in the memory array should not be affected by reducing the number of I/O channels per IC.

The minimal test setup which is cost optimized has 1 I/O channel per IC without any additional terminals required beyond what is available for the standard without increasing the test time. If information beyond a mere pass or fail is required, e.g. as input for a redundancy algorithm, up to 4 I/Os are desirable.

### SUMMARY OF THE INVENTION

The invention relates to a modification of an integrated circuit to increase the throughput of a novel test method by inserting a programmable on-chip register that holds the test data to be written into a memory array or to be read from the array.

A feature of the invention is the use of terminals that are not used during the standard IC operation to control the test register.

This results in a minimized test setup requirement of 1 I/O channel per IC with the capability of flexible array data generation controlled by unused external terminals without increasing the address range in row or column dimension compared to a 16 I/O IC. Optionally, 4 I/O can be activated if information beyond a pass/fail read result is required.

### BRIEF DESCRIPTION OF THE DRAWINGS

FIG. 1 illustrates a register for use with the invention.

FIG. 2 illustrates a test apparatus for use with the invention.

FIG. 3 illustrates operation of a READ operation according to the invention.

FIG. 4 illustrates operation of a WRITE operation according to the invention.

FIG. 5 illustrates normal operation of a circuit having the invention installed.

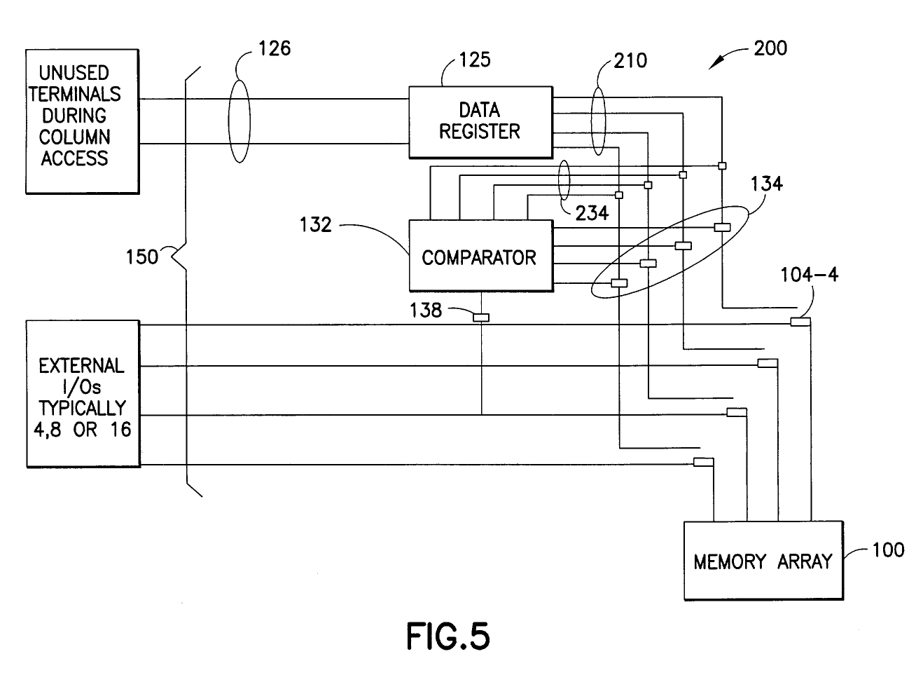

### DETAILED DESCRIPTION

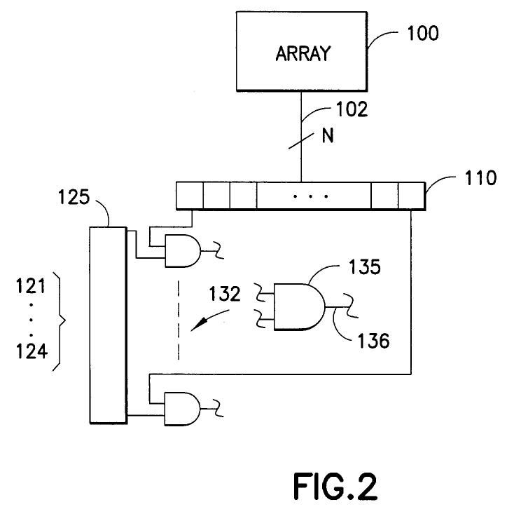

FIG. 2 illustrates a simplified test cycle and apparatus for testing a memory array 100, such as a DRAM, SRAM or EEPROM. A register 110, such as a buffer register that may be an additional internal circuit not used in normal operation holds data read out from array 100. The register is used to supply data to be written to the array during a WRITE operation as well as comparing data coming from the array during a READ operation with reference data from register 125. The register may be used in two ways: to compare data coming from the array during a READ operation (for comparison in a pass/fail test) and writing data from the register into the array, so the source of the write-data is the internal register instead of the external I/O. The register is added to the existing circuitry on the IC. Due to it's nature it requires only a minimal amount of space and can be fit in between existing circuits.

The location of the register in the data path is between the external I/Os and the array.

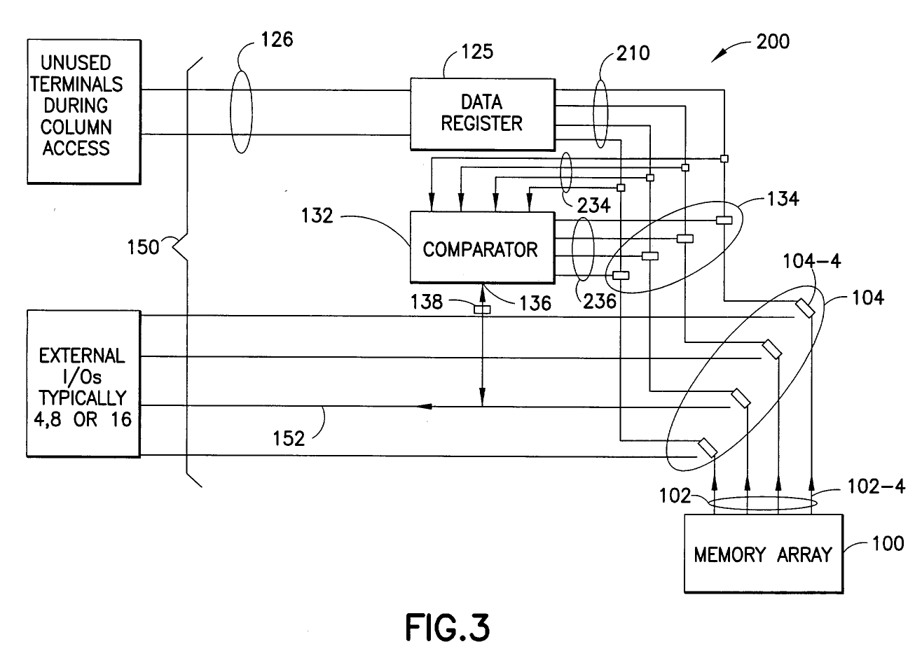

Referring to FIG. 3, a set of I/O 150 are the conventional terminals. A subset 126 of two lines are used to program register 125. An output line 152 contains a pass/fail signal. A supplementary data path 200 is added as part of the invention to the structure normally found in a memory IC. This data path carries data from register 125 to array 100 during a WRITE operation and, during a READ operation, carries data from register 125 to comparison module 132 and from array 100 to comparison module. Two sets of switches 134 and 104 control the flow of data along the path, isolating I/O terminals 150 from the memory array input and output and directing date into comparison module 132.

The control of the internal register is divided in a setup phase and a selection phase. The setup phase programs the content of the register using the ordinary address and control terminals of the IC. This setup sequence is done before the actual test pattern is executed.

After that the register is controlled by means of the ordinarily unused column address terminals.

In the following an example is given to illustrate this technique. The example assumes a 512 Mb DRAM IC. This chips architecture has 15 address terminals (A0 . . . A14). For a 16 I/O configuration there are 13 row addresses (A0 . . . A12)+2 bank addresses (A13,A14) during the row selection. During the column selection there are 10 column addresses (A0 . . . A9)+1 address for selection of manual/auto precharge (A10)+2 bank addresses (A13,A14). The column address has therefore 2 unused address terminals (A11, A12) in the standard IC operation. These two address terminals (A11,A12) will be used for the control of the internal register. In the following we will illustrate writing data of type A, B, C, and D to the array and reading the same.

Setup phase of the internal register:

In the case of a 512 Mb IC we have 2 unused address (A11,A12) pins connected to register 125 through lines 126 during the column selection and therefore can uniquely address 4 register positions. The programming of the data in the 4 register positions is done before the actual test pattern is executed by using the ordinarily available command and address terminals. As we have 4 register positions we can program data type A to register position 0 (A11=0, A12=0), data type B to register position 1 (A11=1,A12=0), data type C to register position 2 (A11=0, A12=1) and data type D to register position 3 (A11=,A12=1)

After the setup phase the IC is put into a special test mode where now data written to the array is derived from the internal register 125 instead of the external I/O terminals and data read from the array is compared to the internal register and presented on 1 I/O 152 to the outside. Optionally the compare result during a read can be presented on 4 I/Os if desired. If more than 4 different data types are required during the writing or reading of the array the setup phase need to be repeated to update the register content before further write or read operations can be performed.

Write operation with register utilization

When in test mode and writing to the array the ordinarily unused address terminals (A11,A12) are utilized to select the desired register position for writing data to the array. In our example, if we want to write data type A to the array we apply the regular column address signals (A0 . . . A9,A10,A13,A14) and the additional control signals for selecting register position 0 (A11=0,A12=0) to the IC during the column address. To write data type B to the array we apply the regular column address signals (A0 . . . A9,A10,A13,A14) and the additional control signals for selecting register position 1 (A11=1,A12=0) to the IC during the column address. To write data type C to the array we apply the regular column address signals (A0 . . . A9,A10,A13,A14) and the additional control signals for selecting register position 2 (A11=0,A12=1) to the IC during the column address. To write data type D to the array we apply the regular column address signals (A0 . . . A9,A10,A13,A14) and the additional control signals for selecting register position 3 (A11=1,A12=1) to the IC during the column address.

Reading from the array using the register:

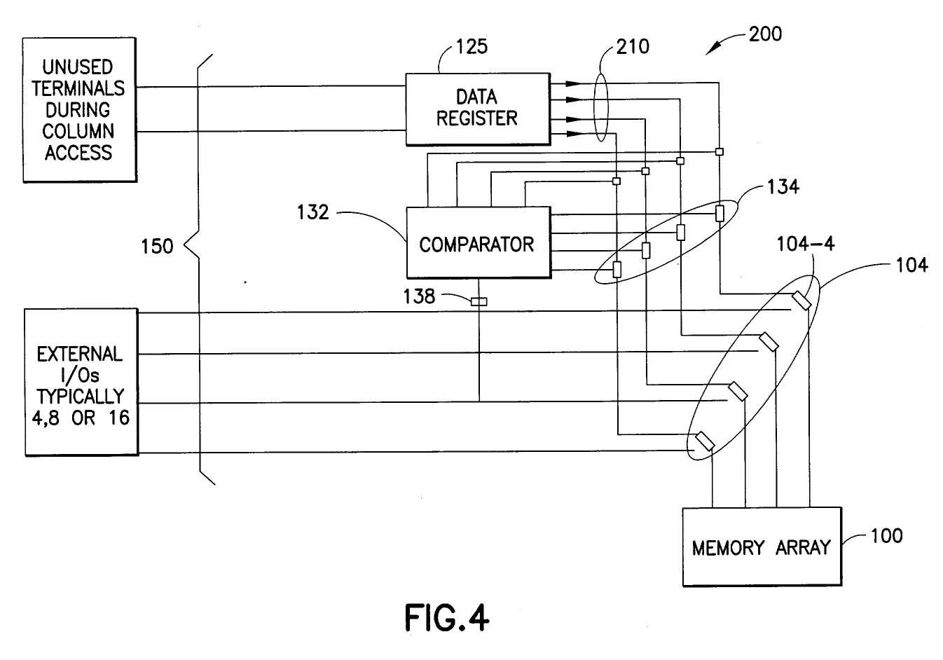

Referring to FIG. 4, data travel from register 125 along lines 210 through switches 134 and 104 to array 100. The switches may be any conventional circuit modules that direct the data as desired, under control of control lines not shown in the Figure.

During a read operation from the array the stored register data is compared to the expected array data in comparison module 132 and the result is then presented to the external I/O on line 136 as a pass/fail result. Line 136 passes through switch 138 that isolates that connection during normal operation. If we want to read array data of the type A we compare it to register position 0 by applying the column address (A0 . . . A9,A10,A13,A14) and the additional control signals for selecting register 0 (A11=0,A12=0). Address types B, C and D work similarly.

Data flows from register 125 to comparison module 132 on lines 210, being isolated by switches 134 from the remainder of the path, to the appropriate inputs of comparison module 132. Switches 134 also direct data from array 100 into the other inputs of unit 132, thus using the data path 200 in two modes during READ and WRITE operations.

The array data compared to the register data is presented to either 1 external I/O on line 152 or optionally 4 external I/Os as pass/fail result.

During normal operation, switches 104 direct data to and from the I/O on the normal path, isolating the special data path 200. In the drawings, the input to array 100 is shown as only four lines 102 for simplicity. There will be a greater number used in arrays that have a x8, x 16 or other number of lines into the array.

Accordingly, the test data read from the array are to be compared with reference data in register 125. The comparison is illustrated for purposes of explanation, by a set of AND circuits 132 that will compare each bit in an N-bit output with the corresponding reference data that was written into the array. The outputs of all the AND circuits 132 are fed into an N-bit AND circuit 135 that puts out a signal on a single line indicating whether that particular set of output data is entirely correct or not.

Those skilled in the art will readily be able to elaborate on this highly simplified example to examine individual bits of the data in order to decide which columns to replace, but that is not relevant for our present purposes of explanation.

According to the invention, one of a set of reference data schematically illustrated as being stored in the box to the left of the figure and denoted 121-124 is written into the relevant cells of the array (through a data path not shown) and the output is then compared with the original data in comparison circuit 132.

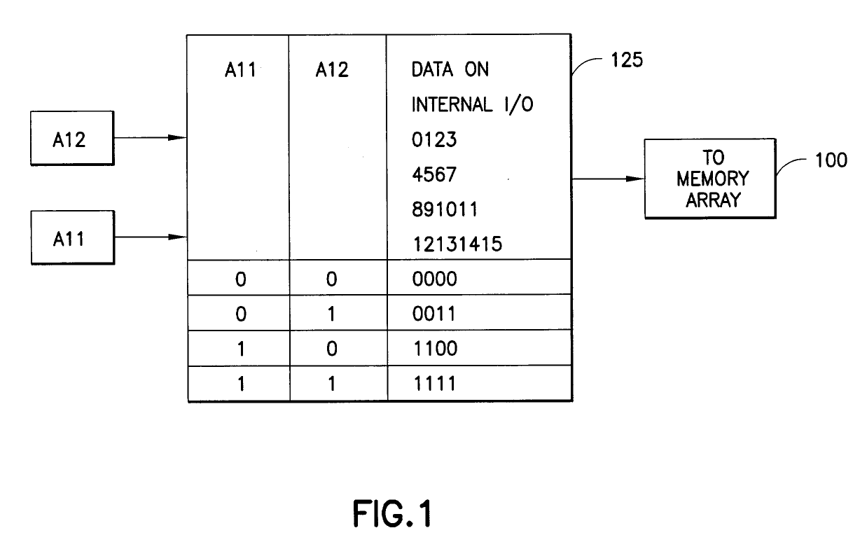

Referring now to FIG. 1, there is shown a portion of hardware in a memory chip for use with the invention. According to the invention, a register 125 is added to the hardware in the memory chip to store a set of n reference data. The external hardware can specify which member of the set is to be fed into the array by use of two terminals A11 and A12. Box 125 illustrates on the right column binary data that can be fed into the array when the control signals on terminals A11 and A12 have the values specified. For ease in illustration, a 4-bit example is shown, but any appropriate number adapted to the width of the test vector may be used. FIG. 1 shows a four-bit vector that is mapped into a sixteen-bit vector, e.g. the 4-bit vector is a-b-c-d and is mapped into the 16 bit vector as a-b-c-d-a-b-c-d-a-b-c-d-a-b-c-d with one load. This is shown as an example and other memory arrays may use different vector lengths.

During the set-up process for the test operation, data will be loaded into register 125 by any convenient method, e.g. by loading the data into the regular data terminals and setting signals on control terminals that control the process of routing the data away from its usual path into the array and into the register 125.

In the case that the regular data terminals are not all available in a minimized tester setup, the setup is done via test mode and uses non-data terminals.

The data can be changed and reprogrammed at any time during the test program by sending appropriate signals to the controller or CPU that controls the test operation. The storage register is loaded with a test mode.

Since different manufacturers of test equipment have different hardware and different control methods, this explanation uses a generic example. The memory chip used in this example uses terminals 0 . . . 10 to specify the memory addresses. Since terminals 11/12 are not used for that purpose, they are available for the invention. We use these two terminals for the register selection. The chip architecture in this case restricts us to two unused terminals (11/12) during the column address an therefore the maximum number of registers is four in this implementation. The reprogramming of the internal register is required only on rare occasions, as four positions are adequate in most cases.

The particular example illustrated is based on a 512 Mbit DRAM chip that has fourteen address pins. During a row selection, all fourteen address pins are used but during a column access only ten address pins are used and pins A11/A12 are “don't care” bits. We use these two bits for the purpose of selecting the register position. Many other choices of pins may be available on other chips.

One of the advantageous features of the invention is that the test process does not require loading test data through the external pins of the chip. Another advantageous feature of the invention is that most of the hardware used for the method is already present. Only the register 125, externally programmable through unused terminals (unused during the test procedure, of course) is added in order to carry out the invention.

While the invention has been described in terms of a single preferred embodiment, those skilled in the art will recognize that the invention can be practiced in various versions within the spirit and scope of the following claims.

What is claimed is:

1. An integrated circuit comprising:
a memory array;
at least one register for holding data read out from said memory array; comparison means for comparing the contents of said register with stored reference data during a test operation; and
means for selecting one of a set of N stored reference data for use in a test operation in response to a set of control signals on external terminals of said integrated circuit that are not otherwise used during said test operation.

2. An integrated circuit according to claim 1, in which:
said means for selecting is connected to a set of terminals not used during a normal test operation.

3. An integrated circuit according to claim 2, in which said terminals are column address terminals.

4. An integrated circuit according to claim 1, in which:
said N stored reference data are stored in a programmable register;
data travel from said programmable register to said array on a first controllable data path; and
data travel from said array to a comparison module on a second controllable data path overlapping said first data path.

5. An integrated circuit according to claim 4, in which:
said second data path includes a set of switches that connect said programmable register to said array in a first mode and direct data from said array to said comparison module while isolating said programmable register in a second mode.

6. An integrated circuit according to claim 2, in which:
said N stored reference data are stored in a programmable register.

7. An integrated circuit according to claim 6, in which:
said N stored reference data are stored in said programmable register during a setup period.

8. An integrated circuit according to claim 1, comprising means for writing stored data held in said register into said memory array through a first controllable data path containing a set of switches for alternately connecting said register and a comparison module with said array.

9. An integrated circuit according to claim 8, in which:
said N stored reference data are stored in a programmable register.

10. An integrated circuit according to claim 9, in which:
said N stored reference data are stored in said programmable register during a setup period.

11. An integrated circuit according to claim 8, in which:
said memory array is a DRAM.

12. An integrated circuit according to claim 8, in which:
said memory array is an embedded DRAM array.

13. An integrated circuit according to claim 8, in which:
said memory array is an SRAM.

14. An integrated circuit according to claim 8, in which:
said memory array is a EEPROM.

15. A method of testing a memory array in an integrated circuit having at least one register for holding data read out from said memory array and a controllable register for storing at least two test vectors comprising:
loading said test vectors in said controllable register during a test setup period;
cycling though said locations in said memory array and
(a) loading a test vector in a test portion of said memory array from said controllable register along a first data path;
(b) reading out the contents of said test portion of said memory array and directing said contents to a comparison module through a second data path overlapping said first data path; and
(c) comparing said contents with said test vector; and
controlling said controllable register by placing signals on external terminals of said integrated circuit that are not used during testing to change said test vector from a first test vector to a second test vector during a test.

16. A method according to claim 14, in which said external terminals are column address terminals.

17. An integrated circuit according to claim 14, in which:
said memory array is a DRAM.

18. An integrated circuit according to claim 14, in which:
said memory array is an embedded DRAM array.

19. An integrated circuit according to claim 14, in which:
said memory array is an SRAM.

20. An integrated circuit according to claim 14, in which:
said memory array is a EEPROM.
